(19) United States
(12) Patent Application Publication
(10) Pub. No.: US 2017/0204512 A1
(43) Pub. Date: Jul. 20, 2017

(54) Method for Baking Coated Printing Plates

(71) Applicants: Gerd Steinhoff, Bonn (DE); Stefan Neumann, Bonn (DE)

(72) Inventors: Gerd Steinhoff, Bonn (DE); Stefan Neumann, Bonn (DE)

(73) Assignee: Hydro Aluminium Rolled Products GmbH, Grevenbroich (DE)

(21) Appl. No.: 15/480,193

(22) Filed: Apr. 5, 2017

Related U.S. Application Data
(63) Continuation of application No. PCT/EP2015/074510, filed on Oct. 22, 2015.

(30) Foreign Application Priority Data
Oct. 22, 2014 (EP) 14189964.1

(51) Int. Cl. C23C 14/58; B41N 1/08; B41C 1/00

(52) U.S. Cl. CPC C23C 14/5806; B41C 1/00; B41N 1/083

(57) ABSTRACT

The invention relates to a method for burning in a coating of an aluminium or an aluminium alloy printing plate support, in the case of which the printing plate is heated to a burning in temperature, maintained at this temperature for a predefined duration and subsequently cooled. Deformations can be minimised even further after the burning in process if at least in a temperature range between 150° C. and the burning in temperature, preferably 100° C. and the burning in temperature, the temperature differences of the metal temperature of the printing plate measured along a line in the longitudinal direction of the printing plate during the heating and cooling are maximum 40° C. over a length of 40 cm and the temperature differences of the metal temperature of the printing plate measured along a line perpendicular to the longitudinal direction are less than 10° C. during the heating and cooling.

### CROSS-REFERENCE TO RELATED PATENT APPLICATIONS

This patent application is a continuation of PCT/EP2015/074510, filed Oct. 22, 2015, which claims priority to European Application No. 14189964.1, filed Oct. 22, 2014, the entire teachings and disclosure of which are incorporated herein by reference thereto.

### FIELD OF THE INVENTION

The invention relates to a method for burning in a coating of a printing plate wherein the printing plate comprises aluminium or an aluminium alloy as the printing plate support material, in the case of which the printing plate is heated to a burning in temperature, maintained at this temperature for a predefined duration and subsequently cooled. In addition, the invention also relates to a continuous furnace for carrying out the method according to the invention.

### BACKGROUND OF THE INVENTION

Offset printing plates mainly consist of a thin printing plate support made of aluminium sheet metal with a thickness of 0.1 to 0.5 mm and a coating applied to the aluminium, usually in the form of a light-sensitive layer which can be burned in by thermal heating depending on the application. The light-sensitive layer cures chemically or is chemically cross-linked by the temperature effects. A method and a device for burning in the coating on a printing plate support, hereinafter referred to as burning in the printing plate, are disclosed in the published German patent application DE 41 34 161 A1 in the case of which or by means of which printing plates are subjected to a continuous burning in process by continuous feeding to a burning in furnace designed as a continuous furnace. It is found in the mentioned published patent application that the printing plates tend to deform, if an uneven temperature distribution is generated on the printing plate. In order to avoid this, a plurality of measures are proposed. On the one hand, it is proposed to slightly deform the printing plate during heating and to avoid a random wave formation of the printing plate via the introduced prestress. Furthermore, through the radiating source an even temperature distribution is intended to be achieved over the width, by the radiating source having a greater intensity transverse to the conveying direction towards its edges. Lastly, changing temperatures of the radiating sources as well as heated conveying means are also used in order to achieve this aim. The inlet speed of the printing plate into the furnace region as well as the outlet speed out of the furnace region should also be increased with respect to the conveying speed in the furnace region.

Although various measures are known from the prior art to design the temperature distribution as homogenously as possible, problems with deformations after the burning in process occur in particular with large-format printing plate supports. In spite of the measures proposed in the prior art, the deformations in the case of continuous burning in are so large that printing plate supports can to some extent no longer be used. In particular, this occurs more frequently in the case of large-surface printing plate supports. The wave heights of the deformations of the printing plates are partially more than 6 mm. In particular, it was not known hitherto which temperature gradients of the metal temperature in the printing plate support actually lead to a strong wave formation so that no targeted avoidance or reduction of the wave formation was achieved. Therefore, the published patent application DE 41 34 161 A1 also referred to this as a random wave formation. In addition, it was not known whether the internal stresses in the aluminium support or the stresses introduced by the heat treatment process are relevant for the wave formation of the burned in printing plate support. The measures mentioned in the published German patent application DE 41 34 161 A1 are meant to primarily serve for achieving an even temperature distribution.

### BRIEF SUMMARY OF THE INVENTION

The object of the present invention is thus to propose a method for burning in printing plates or coated printing plate supports, in particular large-format printing plates, whereby the deformations can be specifically minimized after the burning in process. In addition, a continuous furnace should also be proposed which can carry out the method according to the invention.

According to a first teaching of the present invention, the indicated object is achieved in that at least in a temperature range between 150° C. and the burning in temperature, preferably 100° C. and the burning in temperature, the temperature differences of the metal temperature of the printing plate measured along a line in the longitudinal direction of the printing plate during the heating and during the cooling are maximum 40° C., maximum 30° C. or maximum 20° C. over a length of 40 cm and the temperature differences of the metal temperature of the printing plate measured along a line perpendicular to the longitudinal direction are less than 10° C. during the heating and during the cooling.

It has been recognized that in a temperature range of between 150° C. and the burning in temperature or 100° C. and the burning in temperature both the heating process and the cooling process are critical with regard to temperature differences of the metal temperature during the burning in. The reason for this lies in the regions of the printing plate which undergo plastic and elastic deformations to different extents. It has indeed be known that an even temperature distribution during the heating leads to a reduction of the deformation of the printing plate, however, the fact that the cooling process also plays a very important role had not been known hitherto. It was also known through simulations that a higher sensitivity of the printing plates to temperature differences exists in the transverse direction than in the longitudinal direction. The longitudinal direction corresponds in the present case to the transport direction since printing plates are usually transported correspondingly aligned in continuous furnaces. The transverse direction is thus always perpendicular to the transport direction in the present case. By maintaining the temperature differences according to the invention, it is thus possible to significantly reduce the undesired wave formation in the case of burned in printing plate supports. This applies in particular to large-format or large-surface printing plate supports, which are particularly sensitive here.

The burning in preferably takes place in a furnace in a discontinuous manner, preferably in a batch furnace or in a continuous furnace operated in a discontinuous manner. The discontinuous course of the burning in process is, in contrast to the teaching of the published German patent application DE 41 34 161 A1, advantageous since there is the possibility when discontinuously burning in the printing plate to heat the entire printing plate virtually simultaneously to the burning in temperature. The temperature differences on the printing plate are hereby reduced during heating to burning in temperature. The disadvantages of the batch furnace described in DE 41 34 161 A1 can be avoided by a continuous furnace being operated in a discontinuous manner similar to a batch furnace. To this end, the individual printing plate is brought into the continuous furnace in a very short time and completely inserted into the burning in area. In the continuous furnace, the printing plate can remain stationary in the burning in area until the burning in process is completed and it is transported completely out of the burning in area. Unlike DE 41 34 161 A1, the insertion of the printing plate into the burning in area takes place with a speed such that the heating of the printing plate has not yet significantly commenced before the printing plate is arranged completely in the burning in area. While in the prior art approximately two minutes are required for the continuous feeding of the complete printing plate into the burning in area of the continuous furnace, according to the invention the printing plates are transported into the burning in area within a maximum of one minute, preferably within a maximum of 30 s or 20 s, particularly preferably within a maximum of 10 s or 5 s.

According to one embodiment, the individual printing plate is, for this purpose, inserted completely into the furnace with a speed of 25 mm/s to 1000 mm/s, burned in in a stationary manner and moved out of the furnace after the burning in process with a speed of 25 mm/s to 1000 mm/s. The size of the burning in area of the continuous furnace in this case has to correspond to at least the size of the printing plate. After being moved out of the furnace, the cooling takes place uniformly over the length and width such that the temperature gradients according to the invention can be easily maintained. Using this approach, the undesired wave formation can be actively minimized in this respect. Alternatively, a batch furnace with the known disadvantages can also be used for simultaneously burning in a plurality of printing plates which also achieves good flatness properties of the printing plate when maintaining the temperature gradients according to the invention.

The deformation of the printing plate can be further reduced according to a further embodiment of the method in that at least in a temperature range between 150° C. and the burning in temperature, preferably 100° C. and the burning in temperature, the temperature differences of the metal temperature of the printing plate during the heating and during the cooling measured along a line perpendicular to the longitudinal direction are maximum 5° C., preferably maximum 2° C. Both by way of the heating process and by way of the cooling, significantly lower stresses are hereby generated in the aluminium sheet metal of the printing plate and the deformation effectively reduced or even suppressed.

If printing plate supports with a width of at least 300 mm and a length of at least 450 mm, preferably with a width of at least 1000 mm and a length of at least 1400 mm, are used, in particular large-format printing plate supports, for example with width-length formats of 1350 mm×2800 mm or 1600 mm×2900 mm with a burned in coating can be provided, which exhibit particularly reduced deformations after the burning in.

According to a further embodiment of the method, the coating of the printing plate is sufficiently cured and burned in by the burning in temperature of the metal of the printing plate being between 220° C. and 320° C. with a burning in duration of between 1 and 15 minutes, preferably 240° C. to 300° C. with a burning in duration of 2 to 10 minutes. When selecting the burning in temperature, the softening of the printing plate support material must in particular be taken into account, wherein overall a lower temperature level also leads to lower deformations of the printing plate after the burning in.

According to a further embodiment of the method, the printing plates are transported during the burning in process via transport means, wherein transport means are used which prevent or significantly reduce heat dissipation from the printing plate support to the transport means. The influence of the transport means on the temperature distribution of the printing plate is hereby significantly reduced so that a homogenous temperature distribution of the printing plate is not disrupted by the transportation of the printing plate. Transport means are for example conceivable which comprise materials which have a particularly low heat conductivity, i.e. for example less than 1 W/mK e.g. temperature-resistant plastic or epoxide resin. Furthermore, it is conceivable to minimize the contact of the transport means with the printing plates in terms of surface area so that very little heat can be transferred from the transport means to the printing plates or from the printing plates to the transport means via the reduced contact surface. Alternatively, as is known from the prior art, there is the possibility of using heated transport means which, however, then also ideally consist of materials with low heat conductivity so that undesired heat dissipation and thus an inhomogeneous temperature reduction at the contact points with the transport means is prevented.

Particularly preferably the cooling is carried out using cooling means, in particular using convective cooling media such that the entire printing plate support is simultaneously cooled in a controlled manner during the cooling. The cooling process can also take place in a discontinuous manner so that the cooling of a printing plate support does not cover the printing plate support in sections, but rather always cools down said printing plate support uniformly over its whole surface. For example, this can take place via a tempered, gaseous cooling medium. Attention must be paid that the cooling process uniformly covers the entire printing plate support in length and width. The printing plates are preferably cooled in the outlet area from the burning in temperature to below a maximum of 100° C., preferably below a maximum of 50° C. or below a maximum 30° C.

Insertion into an “automatic washing machine”, which uses a liquid medium, should also therefore take place only after cooling to below a maximum of 100° C., preferably below a maximum of 50° C., particularly preferably below a maximum of 30° C., in order to keep the temperature difference low during the very rapid cooling by the washing medium.

According to a further teaching of the invention, the above-mentioned object is achieved by a continuous furnace having a burning in area for heating and maintaining a printing plate at a burning in temperature and means for transporting the printing plate to be burned in into the burning in area and means for transporting the printing plate out of the burning in area is achieved in that the burning in area of the continuous furnace is at least the size of the printing plate, wherein the means for transporting the printing plate into the burning in area and the means for transporting the printing plate out of the burning in area are designed for the discontinuous transport of the printing plate into the burning in area and out of the burning in area.

The means for transporting the printing plates into the burning in area of the continuous furnace and out of the burning in area provide discontinuous transport according to the invention if they can transport the printing plate with a suitable speed into the burning in area so that the printing plate has not yet been significantly heated before it is arranged completely in the burning in area. For example, this can be achieved in that the printing plate is located completely in the burning in area using the transport means after a maximum of one minute, after a maximum of 30 s, particular preferably after a maximum of 20 s or maximum 10 s or a maximum of 5 s and is heated there over its entire surface. Temperature differences during heating can be hereby significantly reduced since the entire printing plate is heated simultaneously, virtually in a stationary manner. Transport means are required for removal out of the burning in area which carry out complete removal from the burning in area within a maximum of 1 minute, maximum 30 s or preferably within a maximum of 20 s. The short duration for inserting the printing plates into the burning in area as well as the removal ensures that, as already mentioned, the heating and also the cooling can take place virtually over the entire surface, so practically stationary, and thus lower temperature differences or gradients can be achieved.

Preferably, according to one embodiment of the continuous furnace, at least one wire belt conveyor that can operate in a discontinuous manner is provided as means for transporting the printing plate into the burning in area and out of the burning in area. Wire belt conveyors, on the one hand, offer the possibility of easily transporting the printing plates without there being large-surface contact between the transport means and the printing plate which would lead to heat dissipation and thus to temperature differences. Unlike as it is known from the prior art, the wire belt conveyors can be operated in a discontinuous manner, i.e. the conveying speed of the wire belt conveyor is changeable depending on the position of the printing plate in the continuous furnace. For example, a wire belt conveyor can convey the printing plate with high speed into the burning in area of the continuous furnace, as soon as the printing plate is in the burning in area, reduce the speed to zero or close to zero and after the burning in remove the printing plate with high speed out of the burning in area.

According to one embodiment, the means for transporting the printing plates into the burning in area and out of the burning in area of the continuous furnace have due to the geometry a reduced contact surface and/or a material with a low heat conductivity in the contact regions with the printing plates. The aim of these measures is to reduce the heat dissipation from the printing plate during transport. A material with a low heat conductivity of for example less than 1 W/mK, but also small contact surfaces can further reduce the heat conduction and thus contribute to achieving low temperature differences in the printing plate during burning in and cooling. Small contact surfaces are for example achieved by raised and curved contact regions such that only a tangential contact is developed between the transport means and the printing plate. In principle, heated or heatable transport means can also be used in order to adapt the temperature of the transport means to the printing plate temperature and to allow only low heat dissipation.

If an inlet area is provided in which the printing plates are heated from room temperature to maximum 150° C., preferably maximum 100° C. and out of which the printing plates can be transported into the burning in area, according to a further embodiment of the invention, the temperature difference to the burning in area can be reduced gradually such that the risk of large temperature differences on the printing plate is reduced during heating to the burning in temperature. It has also been found that the mechanical properties of the printing plate do not change so significantly up to these temperatures. Undesired deformations of the printing plate thus virtually do not occur in the inlet area.

The same also applies when according to a further embodiment of the continuous furnace at least one outlet area is provided in which the printing plate is cooled from a maximum of the burning in temperature to a maximum of 150° C., preferably a maximum of 100° C. or a maximum of 60° C.

The performance of the continuous furnace can be improved according to a further embodiment by the inlet area and the outlet area of the continuous furnace being designed as a buffer or store and being able to receive a plurality of printing plates to be heated or to be cooled.

Lastly, according to a further embodiment, a rinsing device is provided which is provided on the outlet side of the outlet area and in which the printing plates are rinsed with a liquid rinsing medium and further cooled. The printing plates can be efficiently and completely cooled, for example to room temperature and simultaneously cleaned via the rinsing station.

### BRIEF DESCRIPTION OF THE SEVERAL VIEWS OF THE DRAWING

Furthermore, the invention will be explained in more detail based on exemplary embodiments in connection with the drawing. The drawing shows in:

FIG. 1 depicts a printing plate support in a schematic perspective view;

FIG. 2 depicts a schematic sectional view of an exemplary embodiment of a continuous furnace operating in a discontinuous manner;

FIG. 3 likewise depicts a schematic view of a second exemplary embodiment of the method according to the invention with a batch furnace; and

FIG. 4 depicts a continuous furnace operating in a discontinuous manner with an inlet and outlet area in a schematic sectional view.

### DETAILED DESCRIPTION OF THE INVENTION

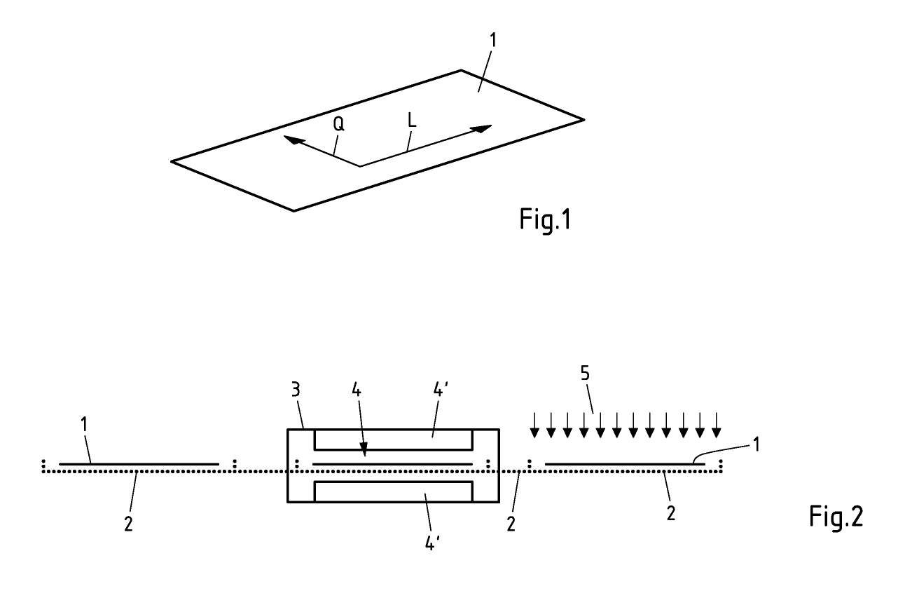

In FIG. 1, a printing plate 1, which usually has a rectangular form, is depicted in a schematic perspective view. The formats used are generally at least 300 mm in width and at least 1000 mm in length. Large-format printing plates 1 preferably comprise a width of at least 1000 mm and a length of at least 2000 mm. Common large-format printing plates have for example the following width to length ratios: 1350 mm×2800 mm or 1600 mm×2900 mm. The printing plate 1 consists in this regard of an aluminium or aluminium alloy sheet metal as the printing plate support having a thickness of 0.1 mm to 0.5 mm. The printing plate 1 comprises a coating, for example a light-sensitive coating, on the support which should be burned in.

In order to examine the phenomenon, printing plates 1 are firstly examined that are burned in with conventional methods, wherein the printing plate was firstly divided into a plurality of measuring surfaces on which the temperature of the metal of the printing plate was measured for example via a pyrometer. The temperatures were measured during the burning in process, during the heating process and also during the cooling process. The elastic and plastic deformation of the corresponding regions of the printing plate was then simulated based on the temperature curves and the stresses arising in the sheet metal distributed over the surface of the printing plate were determined therefrom. The deformations calculated therefrom were compared with the deformations that actually occurred so that conclusions could be drawn regarding the temperature profile to be set of the printing plate.

It was determined that the temperature distribution of the metal temperature of the printing plate in the longitudinal direction L may comprise temperature differences of a maximum of 40° C. over a distance of 40 cm both during the heating and also during the cooling in order to limit deformations. Exceeding this temperature difference leads to greater prestresses in the printing plate after the burning in process and thus to an irreversible deformation of the printing plate. The deformation leads to undesirably large wave formation and rejection of printing plates.

At the same time, it was determined that the printing plate reacts significantly more sensitively to temperature differences in the transverse direction Q, thus perpendicular to the longitudinal direction and temperature differences of less than 10° C. perpendicular to the longitudinal direction have to be maintained in order not to lead to undesirably strong wave formation. The maximum temperature difference transverse to the longitudinal direction during the burning in or cooling process is 5° C., particularly preferably maximum 2° C. such that the wave formation can be reduced.

In order to achieve this, the burning in can be carried out in a discontinuous manner in a continuous furnace. FIG. 2 for this purpose shows for example a continuous furnace 3 operating in a discontinuous manner. The printing plate 1 is for this purpose transported on transport means 2 into the burning in area 4 and the heating thereof only commences there. The transport means 2 can be designed for example as a wire belt conveyor that can be operated in a discontinuous manner in order to transport the printing plate into the burning in area. The burning in area 4 of the continuous furnace is at least as large as the printing plate 1 itself. When the printing plate is arranged in the burning in area of the continuous furnace 3, the wire belt conveyor 2 stops the transport process until the printing plate 1 is burned in. The wire belt conveyor 2 can also comprise materials which have a particularly low heat conductivity at least in the contact regions with the printing plate 1 in order to avoid heat dissipation or an uneven heating of the printing plate 1. In particular, the contact surfaces of the transport means 2 with the printing plate 1 comprise corresponding materials. The contact surfaces can for example consist of temperature-resistant epoxide resin with a heat conductivity of less than 1 W/Km. The contact surfaces of the transport means 2 can in the cross section also comprise radii such that only one tangential contact point with the printing plate 1 is provided. The contact to the printing plate 1 which is very small in terms of surface area also has a positive effect on reducing the heat dissipation from the printing plate 1.

Wire belt conveyors 2 are preferably used as transport means which ensure particularly small contact surfaces to the printing plate 1 via the wire mesh. The wire belt conveyor 2 conveys the printing plate 1 into the burning in area 4 of the burning in furnace 3. As soon as the printing plate is arranged in the burning in area 4, the speed of the wire belt conveyor 2 is reduced to zero and the printing plate 1 is then burned in in a virtually stationary manner in the burning in area 4. After the virtually stationary burning in of the printing plate, the printing plate is removed via the wire belt conveyor out of the burning in area 4 with high speed and cooled over its whole surface. A discontinuous operation of the continuous furnace 3 or burning in furnace 3 is thus ensured by wire belt conveyors 2 that can be operated in a corresponding manner.

However, it is also conceivable to use other transport means that can be operated in a discontinuous manner.

As already mentioned, heating of the printing plate 1 via the heating means 4′ preferably only takes place when the printing plate 1 is positioned in the burning in area 4 of the continuous furnace 3. For example, a combination of radiation and convective heating can heat the printing plate particularly effective, but also homogenously. Since only particularly small temperature differences can be tolerated in the transverse direction, good temperature control of the burning in process plays an important role. The positioning of the printing plate 1 in the burning in area 4 of the continuous furnace 3 preferably takes place within a maximum of one minute, maximum 30 s or preferably within a maximum of 20 s, particularly preferably within a maximum of 10 s or 5 s. The transport means must ensure transport speeds adapted to the geometry or to the size of the printing plate 1. The continuous furnace 3 is operated in a discontinuous manner due to the printing plate 1 remaining in the continuous furnace for the duration of the burning in.

The burning in temperature of 210° C. to 320° C. or 220° C. to 300° C. is maintained for 1 to 15 minutes, preferably 2 to 10 minutes and the printing plate 1 is subsequently cooled. For this purpose, the printing plate 1 preferably remains on the transport means, here the wire belt conveyor. The transport means is then simultaneously cooled in a convective manner via a cooling medium 5 with the printing plate 1. This cooling process is also carried out in a controlled manner such that the entire printing plate is simultaneously homogenously cooled. It was found that the temperature differences to be maintained in the longitudinal direction L are a maximum 40° C. over 40 cm or in the transverse direction Q, perpendicular to the longitudinal direction 10° C., preferably 5° C. particularly preferably 2° C., otherwise undesirably strong wave formation may occur. The wave height can be reduced by these measures after the burning in of the printing plate 1 to significantly below 6 mm. The rejection of printing plates after burning in is hereby significantly reduced and to some extent use of the printing plates is hereby only enabled.

In order to maintain the specifications according to the invention for the temperature on the printing plate, the temperature of the printing plate has to be measured at least once in the process over the entire surface in order to adjust the burning in device. For this purpose, a temperature measurement with pyrometers takes place in the process. The temperature of the printing plate has to be measured already during inserting of the printing plate into the burning in furnace or continuous furnace 3. The heating means 4′ are then to be adjusted with regard to their heat output such that the temperature differences required according to the invention are maintained during the heating and burning in. The same is also carried out for the cooling process and the adjustment for example of the throughput rates of the cooling media. The adjustment of the heating means and optionally also the cooling means with regard to the heating output/cooling output per surface element is very specific and must therefore be individually adapted to the conditions present. Independent of the parameters of the respective system for burning in the printing plates, the method according to the invention ensures a notable reduction of undesired deformations of the printing plate.

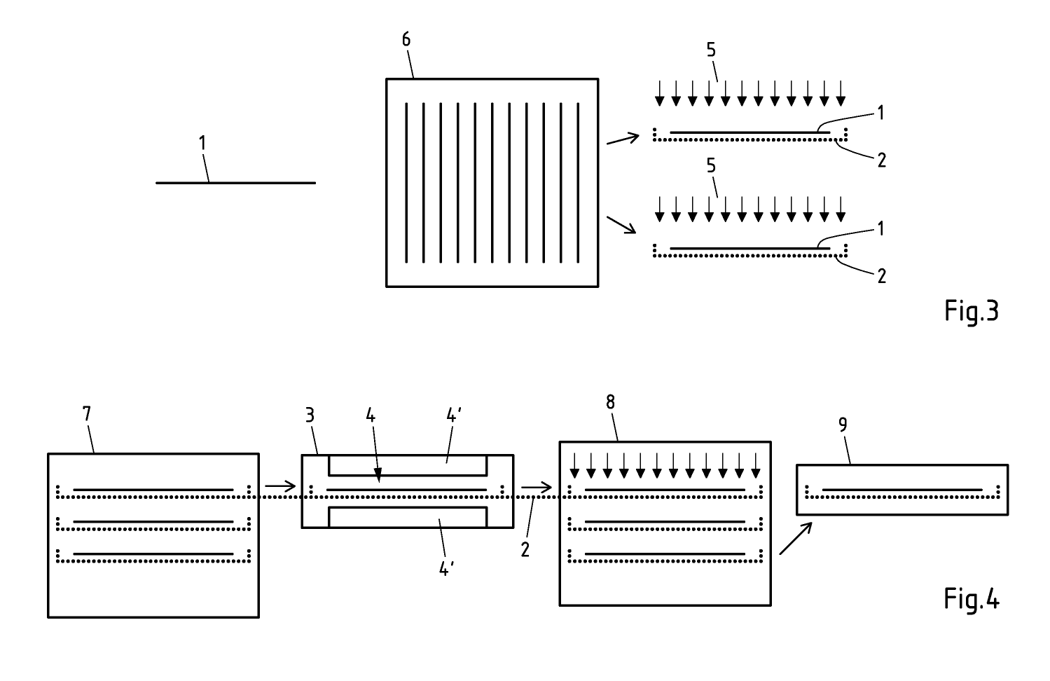

FIG. 3 schematically shows a further exemplary embodiment of the method according to the invention using a batch furnace 6 into which a plurality of printing plates 1 can be inserted. By using the batch furnace 6, the capacity of the burning in process can be increased and therefore all printing plates 1, which are arranged in the batch furnace 6, can be heated very homogenously and evenly. Usually, the printing plates 1 are arranged for this purpose perpendicular in the batch furnace 6. The cooling process subsequently takes place with cooling medium 5. Preferably, a plurality of printing plates 1, arranged in transport means 2 are simultaneously cooled via a cooling medium 5.

If the heating process and the cooling process of the printing plate for burning in the coating takes place in a batch furnace while maintaining the temperature differences according to the invention, the prestresses of the printing plate can be significantly reduced after the burning in process and the size of the undesired deformations substantially reduced.

FIG. 4 shows a device with a continuous furnace 3 that can be operated in a discontinuous manner which in each case comprises an inlet area 7 and an outlet area 9. The printing plates 1 are heated to a temperature of maximum 150° C. in the inlet area 7 designed as a store or buffer and are conveyed out of the inlet area using wire belt conveyors 2 into the burning in area 4. Stockpiling in the inlet area 7 allows the heating process to take place slowly. In addition, a preheated printing plate 1 is already available as soon as a printing plate leaves the burning in area 4 of the continuous furnace 3 and is transported into the outlet area 8. The printing plates 1 can be carefully cooled in the outlet area 9, which is likewise designed as a buffer or store and can receive a plurality of printing plates 1, without the temperature differences being exceeded. The printing plate 1 is subsequently transported into a rinsing device 9 in which the printing plate is cleaned and further cooled at the same time.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method for burning in a coating of a printing plate support, wherein the printing plate comprises aluminium or an aluminium alloy as the support material, in the case of which the printing plate is heated to a burning in temperature, maintained at this temperature for a predefined duration and subsequently cooled,
characterised in that
at least in a temperature range between 150° C. and the burning in temperature, preferably 100° C. and the burning in temperature, the temperature differences of the metal temperature of the printing plate measured along a line in the longitudinal direction of the printing plate during the heating and during the cooling are maximum 40° C. over a length of 40 cm and the temperature differences of the metal temperature of the printing plate measured along a line perpendicular to the longitudinal direction are less than 10° C. during the heating and during the cooling.

2. The method according to claim 1,
characterised in that
the burning in takes place in a furnace in a discontinuous manner, preferably in a batch furnace or in a continuous furnace operating in a discontinuous manner.

3. The method according to claim 1,
characterised in that
at least in a temperature range between 150° C. and the burning in temperature, preferably 100° C. and the burning in temperature, the temperature differences of the metal temperature of the printing plate during the heating and during the cooling measured along a line perpendicular to the longitudinal direction are maximum 5° C., preferably maximum 2° C.

4. The method according to claim 1,
characterised in that
printing plate supports with a width of at least 400 mm and a length of at least 600 mm, preferably with a width of at least 1000 mm and a length of at least 2000 mm are subjected to the burning in process.

5. The method according to claim 1,
characterised in that
the burning in temperature of the metal of the printing plate is between 220° C. and 320° C. with a burning in duration of between 1 and 15 minutes, preferably 240° C. to 300° C. with a burning in duration of 2 to 10 minutes.

6. The method according to claim 1,
characterised in that
the printing plates are transported using transport means which prevent or sharply reduce heat dissipation from the printing plate support via the transport means.

7. The method according to claim 1,
characterised in that
the cooling is carried out using cooling means, in particular convective cooling media such that the entire printing plate support is simultaneously cooled in a controlled manner during the cooling.

8. A continuous furnace for carrying out a method according to claim 1 having a burning in area for heating and maintaining a printing plate at a burning in temperature and means for transporting the printing plate to be burned in into the burning in area and means for transporting the printing plate out of the burning in area,
characterised in that
the burning in area of the continuous furnace is at least the size of the printing plate, the means for transporting the printing plate into the burning in area and the means for transporting the printing plate out of the burning in area are designed for the discontinuous transport of the printing plate into the burning in area and out of the burning in area.

9. The continuous furnace according to claim 8,
characterised in that
wire belt conveyors that can operate in a discontinuous manner are provided as the means for transporting the printing plate into the burning in area and out of the burning in area of the continuous furnace.

10. The continuous furnace according to claim 8,
characterised in that
the means for transporting the printing plate into and out of the burning in area have very low heat conductivity in the contact regions with the printing plates due to the geometry and/or the materials of the contact regions used.

11. The continuous furnace according to claim 8,
characterised in that
an inlet area is provided in which the printing plates can be heated from room temperature to maximum 150° C., preferably maximum 100° C. and out of which the printing plates can be transported into the burning in area.

12. The continuous furnace according to claim 8,
characterised in that
an outlet area is provided in which the printing plates are cooled from the burning in temperature to less than 100° C., preferably less than 50° C. or less than 30° C.

13. The continuous furnace according to claim 8,
characterised in that
the inlet area and the outlet area are designed as a buffer or store and can receive a plurality of printing plates to be heated or to be cooled.

14. The continuous furnace according to claim 8,
characterised in that
a rinsing device is provided which is provided on the outlet side of the outlet area and in which the printing plates are rinsed with a fluid rinsing medium and further cooled.
